(19) United States
(12) Patent Application Publication
(10) Pub. No.: US 2026/0202148 A1
(43) Pub. Date: Jul. 16, 2026

(54) FIN ARCHITECTURE FOR PROMOTING HEAT EXCHANGE

(71) Applicant: THALES, MEUDON (FR)

(72) Inventor: Ivan GRIMARDIAS, SOPHIA ANTIPOLIS (FR)

(21) Appl. No.: 19/134,191

(22) PCT Filed: Dec. 11, 2023
(86) PCT No.: PCT/EP2023/085033

§ 371 Date: May 29, 2025

(30) Foreign Application Priority Data
Dec. 27, 2022 (FR) FR2214520

(51) Int. Cl. F28F 13/00; F28F 1/42

(52) U.S. Cl. CPC F28F 13/003; F28F 1/42; F28F 2215/06

(57) ABSTRACT

A cooling device includes at least one cooling fin, the device being configured to allow a heat-transfer fluid to circulate along the at least one cooling fin in a first direction, a heat exchange being able to be carried out by convection between the at least one cooling fin and the heat-transfer stream, the cooling fin including: a heat exchange surface configured to allow the heat exchange with the heat-transfer fluid, a first wall and a second wall, the first wall and the second wall extending in a plane substantially parallel to the first direction and substantially perpendicular to the heat exchange surface, a cavity contained between the first wall and the second wall, the heat-transfer fluid circulating in the cavity, a heat exchanger contained in the cavity and connected to the heat exchange surface, the heat exchanger having a fractal structure in a plane perpendicular to the first direction of the heat-transfer fluid.

### CROSS-REFERENCE TO RELATED APPLICATIONS

This application is a National Stage of International patent application PCT/EP2023/085033, filed on Dec. 11, 2023, which claims priority to foreign French patent application No. FR 2214520, filed on Dec. 27, 2022, the disclosures of which are incorporated by reference in their entireties.

### FIELD OF THE INVENTION

The invention relates to the cooling of an element producing heat. The invention is applicable in the field of electric machines and power electronics. Specifically, it is known that electronic equipment, computers, and electronics in general generate losses that result in production of heat that it is necessary to evacuate. The evacuation of this heat, ensuring correct operation of the elements mentioned above, therefore becomes a priority. The invention is particularly applicable in the field of on-board electronics where the tendency is to increase the number of items of electrical equipment and therefore the on-board electrical power.

The invention relates more particularly to a cooling fin architecture for such a heat exchanger.

### BACKGROUND

Currently, a large number of electronic systems are equipped with heat exchangers, making it possible to evacuate the heat from the elements dissipating heat energy to a source for evacuation of this heat, in order to allow these electronics to operate under optimal conditions.

Heat exchangers are known today that comprise a set of fins disposed along an axis of movement of a heat-transfer stream for which the heat exchange with a second fluid or the thermal element itself is desired, for example, fins that are straight in the direction of a stream of air passing through the heat exchanger using the fins to extract the heat energy to a fluid at lower temperature, or a fluid using the fins to extract the heat energy generated by an electronic component.

The function of the fins is to allow the heat exchange between two fluids, or a fluid and a solid thermally conductive element, these two elements being at different temperatures. More precisely, the fins are then interfaces used to improve the efficiency of exchanges between the mentioned elements, namely the two heat-transfer fluids or the fluid and the solid element.

However, the use of a single heat-transfer stream sweeping over the heat exchanger is preferred for reasons of compactness and weight. Specifically, the addition of a second heat-transfer fluid and of the entire circuit allowing this second fluid to circulate often generates excess mass and volume that it becomes necessary to take into consideration, especially in the field of aeronautics in which the main problem is the management of the mass of the vehicle.

Consequently, the cooling of an electric machine is today limited by constraints of mass and bulk that the prior art is not capable of overcoming.

Thus, in a configuration for cooling between a heat-transfer fluid carrying out a direct extraction of the heat from the fins of the heat exchanger, an exchange surface in contact with the heat exchanger and with the heat-transfer fluid, at the cooling fins, can be identified in order to allow this thermal extraction.

With the aim of improving this exchange, research is currently being carried out concerning the surface of these fins for contact between the heat-transfer fluid on which the heat exchange is desired and the solid element used for this exchange.

Furthermore, the main methods for producing such fins are stamping or folding, and this limits the shapes and therefore the performance of the heat exchanges.

Thus, it is currently difficult, or even impossible, for technical and manufacturing reasons, to improve this heat exchange at the exchange surface of the fins of the heat exchanger.

### SUMMARY OF THE INVENTION

The invention aims to remedy all or some of the problems mentioned above by proposing fin shapes that make it possible to increase the surface for exchange between the heat source, namely the solid element, and a heat-transfer fluid sweeping over the heat exchanger, allowing the transfer of heat energy. This geometric change has the advantage of increasing the heat exchange surface, making it possible to improve the heat exchange, while at the same time limiting any pressure drop of the heat-transfer fluid or stream passing through the heat exchanger, leading to a reduction in the heat exchange.

To this end, a subject of the invention is a cooling device comprising at least one cooling fin, the device being configured to allow a heat-transfer fluid to circulate along the at least one cooling fin in a first direction, a heat exchange being able to be carried out by convection between the at least one cooling fin and the heat-transfer stream, the cooling fin comprising:
A heat exchange surface configured to allow the heat exchange with the heat-transfer fluid,
A first wall and a second wall, the first wall and the second wall extending in a plane substantially parallel to the first direction and substantially perpendicular to the heat exchange surface,
A cavity contained between the first wall and the second wall, the heat-transfer fluid circulating in the cavity,
A heat exchanger contained in the cavity and connected to the heat exchange surface, the heat exchanger having a fractal structure in a plane perpendicular to the first direction of the heat-transfer fluid.

According to one aspect of the invention, the heat exchanger is connected to the first wall and to the second wall.

According to one aspect of the invention, the heat exchanger is defined so as to maximize the heat exchange surface.

According to one aspect of the invention, the heat exchanger comprises repeats of an elementary pattern.

According to one aspect of the invention, the elementary pattern comprises a largest dimension less than 12 millimeters.

According to one aspect of the invention, the heat exchanger comprises an additional exchange surface, the additional exchange surface representing at least a quarter of the surface contained in the cavity of the cooling fin in the plane perpendicular to the direction of the heat-transfer stream.

According to one aspect of the invention, the elementary pattern is a polygonal pattern.

According to one aspect of the invention, the polygonal pattern is open on at least one side of the polygonal pattern.

According to one aspect of the invention, the elementary pattern comprises a broken vertex.

According to one aspect of the invention, the elementary pattern comprises a folded vertex.

According to one aspect of the invention, the heat exchanger comprises a second elementary pattern, the second elementary pattern being of dimensions smaller than the dimensions of the elementary pattern.

According to one aspect of the invention, the second elementary pattern is a pattern identical to the elementary pattern.

According to one aspect of the invention, the dimensions of the second elementary pattern are smaller by half than the dimensions of the elementary pattern.

According to one aspect of the invention, the heat exchanger comprises a self-similar fractal structure.

The invention also relates to a method for manufacturing a cooling fin of the heat exchanger comprising an additional heat exchange surface, the method comprising the following steps:
Selecting an individual section of the additional exchange surface of the heat exchanger,
Angularly modifying the individual section of the additional exchange surface in a first modification direction, the angular modification consisting in creating an isosceles triangle of which the large base is the selected individual section of the additional exchange surface, in the first modification direction, the isosceles triangle comprising two subdivided sides, and of which the height is equal to the length of the selected individual section of the additional exchange surface multiplied by a predefined factor k, the isosceles triangle being open on the large base,
Selecting a subdivided side from among the two subdivided sides,
Angularly modifying the selected subdivided side in a second modification direction that intersects the first modification direction,
Selecting the other subdivided side from among the two subdivided sides,
Angularly modifying the selected other subdivided side in the second modification direction,
Repeating the previous steps.

According to one aspect of the invention, the second modification direction is substantially opposite to the first modification direction.

### BRIEF DESCRIPTION OF THE DRAWINGS

The invention will be understood better and further advantages will become apparent from reading the detailed description of an embodiment given by way of example, this description being illustrated by the appended drawings in which:

FIG. 1 shows a schematic view in cross section of a cooling fin of a cooling device according to the invention;

FIG. 2 shows a schematic view in cross section of the cooling fin according to a second configuration;

FIG. 3 shows a schematic view in cross section of the cooling fin according to a third configuration;

FIG. 4 shows a schematic view in cross section of the cooling fin according to a fourth configuration;

FIG. 5A shows a schematic view of the cooling fin in FIG. 4 according to a first variant;

FIG. 5B shows a schematic view of the cooling fin in FIG. 4 according to a second variant;

FIG. 6 shows a schematic view in cross section of the cooling fin according to a fifth configuration;

FIG. 7 shows a schematic view in cross section of the cooling fin according to a sixth configuration;

FIG. 8 shows a schematic view in cross section of the cooling fin according to a seventh configuration;

FIG. 9 shows a method for producing a heat exchanger of a cooling fin of a cooling device according to the invention.

For the sake of clarity, identical elements bear the same references in the various figures.

### DETAILED DESCRIPTION

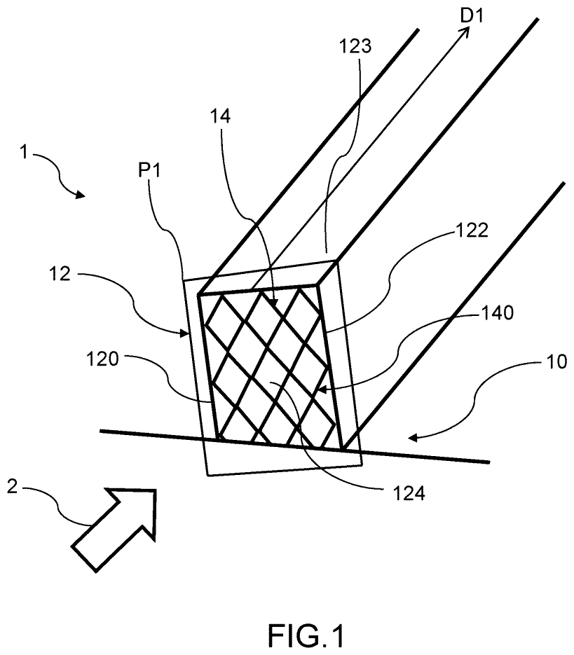

FIG. 1 shows a schematic view of a cooling fin 12 of a cooling device 1 comprising at least one cooling fin 12 as shown. The cooling device 1 is configured to allow a heat-transfer fluid 2 to circulate along the at least one cooling fin 12 in a first direction D1 of flow of the heat-transfer fluid 2. Thus, a heat exchange can be carried out by convection between the cooling fin 12 and the heat-transfer stream 2. In a preferential configuration of the invention, as shown in FIG. 1, the first direction D1 of flow of the heat-transfer fluid 2 is parallel to the direction in which the cooling fin 12 extends. In other words, the heat-transfer fluid 2, which moves parallel to the first direction D1, passes perpendicularly through the cooling fin 12 in a plane P1 perpendicular to the first direction D1 so as to exchange by convection with the cooling fin 12.

In addition, this heat exchange is very efficient for the heat-transfer fluid in proximity to the cooling fin 12, whereas the heat exchange is less efficient, in comparison with the heat exchange by convection between the heat-transfer fluid 2 in direct proximity to the cooling fin 12 and the cooling fin 12 itself.

As a variant, it may be envisaged that the first direction D1 intersects the direction of extension of the cooling fin 12. It can also be envisaged that the heat-transfer fluid 2 passes through the cooling fin 12 in the first direction D1 before exchanging heat with a second fluid of lower temperature.

Furthermore, the cooling fin 12 comprises a heat exchange surface 10 configured to allow the heat exchange with the heat-transfer fluid 2. The heat exchange surface 10 is thus a thermally conductive surface that makes it possible to distribute the heat over the entire heat exchange surface by conduction in order to allow a zone of heat exchange with the heat-transfer fluid 2 all along the cooling fin 12. The heat exchange surface 10 is thus a hot body that requires a quantity of heat to be discharged, whereas the heat-transfer fluid 2 is a cold body of which the function is to exchange with the heat exchange surface 10 and to extract heat. The heat exchange surface 10 advantageously comprises a thermally conductive material. In addition, this heat is transmitted from the heat exchange surface 10 to the heat-transfer fluid 2 that passes through the cooling fin 12 by convection so as to evacuate the heat from the cooling device 1, this heat exchange occurring mainly along the heat exchange surface 10 and in proximity to the heat exchange surface 10.

The cooling fin also comprises a first wall 120 and a second wall 122 extending substantially parallel to the first direction D1 and in a plane substantially parallel to the first direction D1 and substantially perpendicular to the heat exchange surface 10. The first wall 120 and the second wall 122 are thus the load-bearing structure of the cooling fin 12.

In addition, the cooling fin comprises a cavity 124 contained between the first wall 120 and the second wall 122, in which the heat-transfer fluid 2 circulates. In other words, the heat-transfer fluid 2, which exchanges heat with the heat exchange surface 10, passes through the cooling fin 2 between the first wall 120 and the second wall 122 in a manner substantially parallel to the first direction D1.

It may be envisaged to connect the first wall 120 and the second wall 122 so as to define a closed cavity 124 between the first wall 120 and the second wall 122 as shown in FIG. 1. Consequently, the first wall 120 is connected to the second wall 122 by way of the heat exchange surface 10 but also by another upper connection 123.

As a variant, the first wall 120 is connected to the second wall 122 only by way of the heat exchange surface 10. Consequently, the upper connection 123 is then no longer shown and the cavity communicates with an environment external to the cooling fin 12.

However, as observed above, the heat exchange between the hot body, namely the heat exchange surface 10, and the cold body, namely the heat-transfer fluid 2, is effected efficiently along the heat exchange surface 10 and in proximity to the heat exchange surface 10. In addition, this efficiency of the heat exchange between the heat exchange surface 10 and the heat-transfer fluid 2 decreases proportionally with respect to the distance between the heat-transfer fluid 2 and the heat exchange surface 10.

Thus, advantageously, the cooling fin 12 comprises a heat exchanger 14 contained in the cavity 124 and connected to the heat exchange surface 10. The heat exchanger 14 comprises a fractal structure shown in the plane P1 perpendicular to the first direction D1 of the heat-transfer fluid 2.

Thus, the heat exchanger 14 is defined as a structure that is able to increase the heat exchange surface 10 or even to maximize the heat exchange surface 10. In other words, the heat exchanger 14 is an additional heat exchange surface with respect to the heat exchange surface 10, so as to also allow a heat exchange by convection between the heat-transfer fluid 2 and the heat exchanger 14. Specifically, the heat exchanger 14 also has a good conduction capacity such that the heat contained in the heat exchange surface 10 can be conducted into the heat exchanger 14. Consequently, the exchange by convection is no longer effected only between the heat-transfer fluid 2 and the heat exchange surface 10 but also between the heat-transfer fluid 2 and the heat exchanger 14. The heat exchange by convection is thus improved.

Thus, the heat exchanger 14 comprises within its structure repeats of a simple elementary pattern 140. In the configuration in FIG. 1, this elementary pattern 140 is a rhombus connected to the heat exchange surface 10.

The term “fractal” is therefore to be understood as a structure comprising only repeats of a simple elementary pattern 140 extending in the cavity 124. In other words, the fractal structure of the heat exchanger 14 is a structure that is broken up by way of the elementary pattern 140.

Furthermore, the heat exchanger 14 also has the advantage, in addition to increasing the surface for heat exchange with the heat-transfer fluid 2 and improving the heat exchange with the heat-transfer fluid 2, of not impacting the heat-transfer fluid 2 passing through the cooling fin. Specifically, positioning an object so as to impede the movement of the heat-transfer fluid 2 in the first direction D1 generally leads to a deviation of the movement of the heat-transfer fluid 2, a loss in terms of the speed of flow of the heat-transfer fluid 2 in the cooling fin and overall a pressure drop. On the macroscopic scale, this reduction in the pressure of the heat-transfer fluid 2 passing through the cooling fin 12 and the heat exchanger 14 then results in a decrease in the flow rate of the heat-transfer fluid 2 passing through the cavity 124 in particular. Consequently, the heat exchange between the heat exchange surface 10 or the heat exchanger 14 and the heat-transfer fluid 2 is negatively impacted thereby. However, the fractal structure of the heat exchanger 14 has the advantage of improving the heat exchange without impacting, or by sparingly impacting, the pressure associated with the heat-transfer fluid 2 passing through the cooling fin.

Specifically, the wall forming the fractal structure of the heat exchanger 14 is relatively weak so as not to deflect the movement of the heat-transfer fluid 2 in the cavity 124. In addition, this fractal structure ensures good stiffness of the heat exchanger, in addition to the multiple fastening thereof with the heat exchange surface 10.

Thus, the cooling fin according to the invention makes it possible, by way of the heat exchanger 14, to increase the overall heat exchange surface by limiting the pressure drop of the heat-transfer fluid 2 passing through the cooling device 1.

As a variant, and in order to improve the stiffness of the heat exchanger 14, it may be envisaged to connect the heat exchanger 14 to the first wall 120 and to the second wall 122 by way of, for example, the upper connection 123.

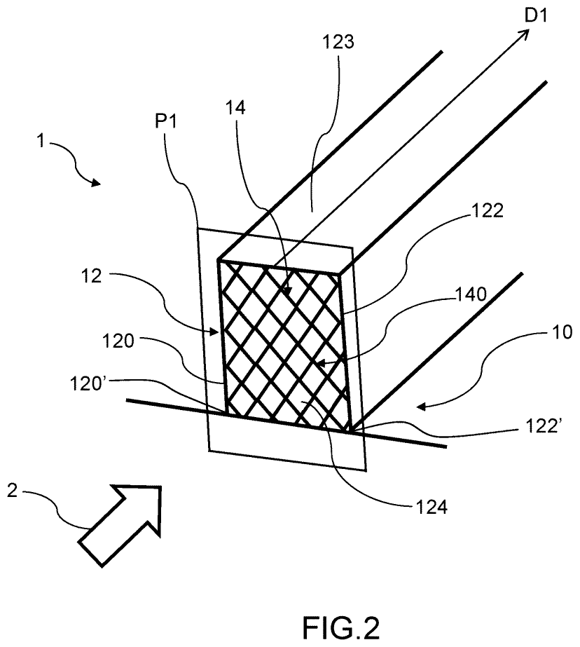

According to a second exemplary configuration, shown in FIG. 2, the heat exchanger 14 can also be directly connected to the first wall 120 and to the second wall 122. This configuration distributes the fastenings of the heat exchanger 14 in the cavity 124 of the cooling fin 12 more uniformly and improves the stiffness of the heat exchanger 14.

In addition, it can also be envisaged that the first wall 120 and/or the second wall 122 conduct heat from the heat exchange surface 10. Consequently, the overall heat exchange surface in the cooling fin is made up of the heat exchange surface 10, the first wall 120, the second wall 122 and the heat exchanger 14. In addition, the heat exchanger 14 then allows better distribution of the heat in the heat exchange surface 10, the first wall 120, the second wall 122 and the heat exchanger 14, and particularly in the first wall 120 and in the second wall 122 or even in the upper connection 123.

Specifically, as stated above, the greater the distance between two bodies, the more difficult the heat exchanger is. Now, this is also the case for the conduction between the heat exchange surface 10 that is the hot body and, for example, the upper connection 123 or else an end of the first wall 120 or of the second wall 122 not directly connected to the heat exchange surface 10.

Consequently, in the absence of the heat exchanger 14, the only thermal path allowing heat to be conducted from the heat exchange surface 10 to the upper connection 123 or else an end of the first wall 120 or of the second wall 122 not directly connected to the heat exchange surface 10 is the thermal path passing via the end 120′ of the first wall 120 and the end 122′ of the second wall 122 connected directly to the heat exchange surface 10 and then passing through the entirety of the first wall 120 or of the second wall 122.

However, the heat is then not entirely transmitted and the upper connection 123 or else the end of the first wall 120 or of the second wall 122 not directly connected to the heat exchange surface 10 is relatively colder than the heat exchange surface 10, and this degrades the heat exchange by convection with the heat-transfer fluid 2 since the temperature differential is reduced.

The heat exchanger 14 makes it possible, by way of its fractal structure, to generate a plurality of thermal paths between various points of the heat exchange surface 10 and these same zones in which the heat exchange is degraded, namely the upper connection 123 or else the end of the first wall 120 or of the second wall 122 not directly connected to the heat exchange surface 10, so as to be able to conduct more heat and therefore to make it possible to improve the heat exchange between these zones and the heat-transfer fluid 2 by convection.

Furthermore, as shown in FIG. 1 and FIG. 2, the elementary pattern 140 is a polygon of rhombus type. This rhombus shape has the advantage of being the polygonal shape that is most easily reproducible while at the same time increasing the total heat exchange surface in the cooling fin 12 in the available volume defined by the cavity 124.

According to a variant, it can be envisaged that the heat exchanger 14 is connected only to the first wall 120 or only to the second wall 122.

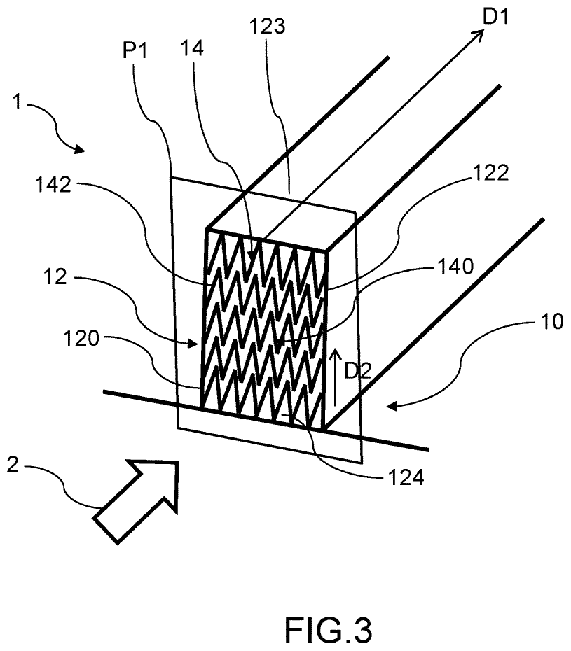

Furthermore, it can also be envisaged that the elementary pattern 140 is an open polygonal pattern, i.e. the polygon is open on one of its sides, as shown in FIG. 3, in which the elementary pattern 140 is a triangle, of which one of the sides is not connected. This configuration has the advantage of making it possible to increase the density of elementary elements 140 in the cavity 124 and to increase the additional heat exchange surface 142 generated by the presence of the heat exchanger 14. The additional heat exchange surface 142 is thus the surface for heat exchange with the heat-transfer fluid 2 of the heat exchanger 14 only.

Specifically, in the plane P1, the elimination of one and the same side of the elementary pattern 140 of triangular shape has the advantage of making it possible to compress the elementary patterns 140 in a direction of the plane P1, namely a second direction D2 according to the configuration shown in FIG. 3.

Consequently, a larger number of elementary patterns 140 can be envisaged in the structure of the heat exchanger 14 and the additional heat exchange surface 142 is increased, improving the heat exchange by convection with the heat-transfer fluid 2.

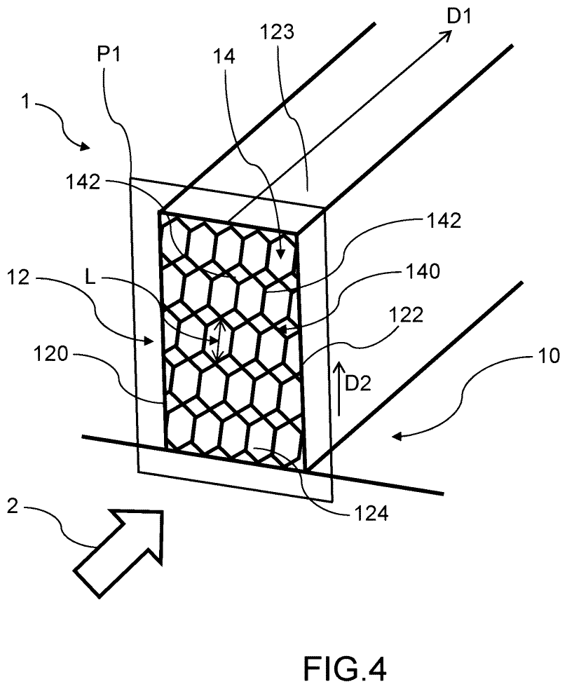

As shown in FIG. 4, it can also be envisaged that the elementary pattern 140 is of hexagonal shape. The hexagonal shape offers the smallest perimeter to fill in space compared with the other known regular polygons. Indeed, of the three regular polygons mentioned above that make it possible to pave a space, namely the cavity 124, the hexagon is the one that offers the smallest perimeter. In addition, this dimension of the hexagonal shape has the advantage of having a projected surface in the plane P1, linked to one and the same thickness of wall between the various shapes, which is the smallest, and this induces a smaller pressure drop compared with the other types of paving.

Thus, the hexagonal shape has the advantage of optimizing the frontal surface, i.e. the surface of the heat exchanger 14 in the plane P1, of the cooling fin 12 seen from the heat-transfer fluid 2 entering the cooling device 1 in the predefined flow direction, with respect to the surface for contact between this same heat-transfer fluid 2 along its route through the cavity 124 and the cooling device 1, by optimizing the quantity of material used for this implementation.

The choice of the hexagon is linked to its ability to “pave” a predefined zone, namely the cavity 124 of the cooling fin 12. The zone is the frontal surface of the heat exchanger 14 in the plane P1 with respect to the direction of flow of the heat-transfer fluid passing through the cavity 124 and the cooling fin 12.

Tiling the cavity in the plane P1 is the way to fill a predefined zone using an identical elementary pattern 140 without this leaving “holes” or unused space between the shapes, or one elementary pattern or shape encroaching onto another.

Furthermore, the elementary pattern 140 can also be defined by a dimension other than its perimeter. By way of indicative example, the elementary pattern 140 may comprise a largest dimension L, as shown in FIG. 4, which represents the longest length contained in the elementary pattern 140 that is observable in the plane P1 perpendicular to the first direction D1. In the case of FIG. 4, for which the elementary pattern 140 is a hexagonal pattern, the longest length of the elementary pattern can be interpreted as the length connecting two opposite vertices of the hexagon, passing through the center of the hexagon.

In the case of an elementary pattern 140 of which the polygonal shape comprises four sides, as shown in FIG. 1, the longest length of the elementary pattern 140 is its diagonal.

In addition, this largest dimension L is a length less than twelve millimeters. By way of indicative example, the longest length of the elementary pattern 140 is between one millimeter and twelve millimeters.

Thus, it can be envisaged, by virtue of the small dimensions of the elementary patterns 140, that the additional exchange surface 142 of the heat exchanger 14 represents at least a quarter of the projected surface contained in the cavity 124 of the cooling fin 12 in the plane P1 perpendicular to the direction D1 of the heat-transfer stream 2.

As stated above, the elementary pattern 140 may be a simple polygonal pattern like the patterns cited above or else form part of a non-exhaustive list comprising a heptagon, an octagon or else a decagon and other regular polygon.

Furthermore, concerning the shapes of elementary pattern 140 with more than four sides, and preferentially in a configuration with a hexagonal elementary pattern, there can be envisaged various configurations for thermal connection between the heat exchange surface 10 and the additional heat exchange surface 142 of the heat exchanger 14.

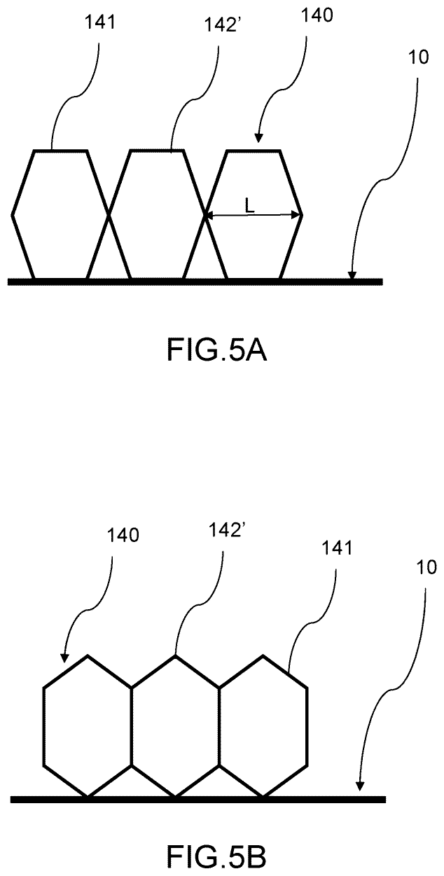

Specifically, as shown in FIG. 5A, it can be envisaged that one side 141 of the elementary pattern of polygonal shape, and in the case of FIG. 5A of hexagonal shape, is connected to the heat exchange surface 10 so as to improve the thermal connection between the heat exchanger 14 and the heat exchange surface 10.

According to a variant shown in FIG. 5B, it can also be envisaged that the thermal connection between the heat exchanger 14 and the heat exchange surface 10 is effected by way of a vertex 142′. Consequently, each of the elementary patterns 140 that are connected to each other parallel to the heat exchange surface 10 is thermally connected by way of a side 141, improving the heat exchange between two adjacent elementary patterns 140 and thus improving the thermal conductivity of the heat exchanger 14.

As stated above, the elementary pattern 140 can therefore be a polygonal pattern that therefore comprises sides 141 and broken vertices 142′.

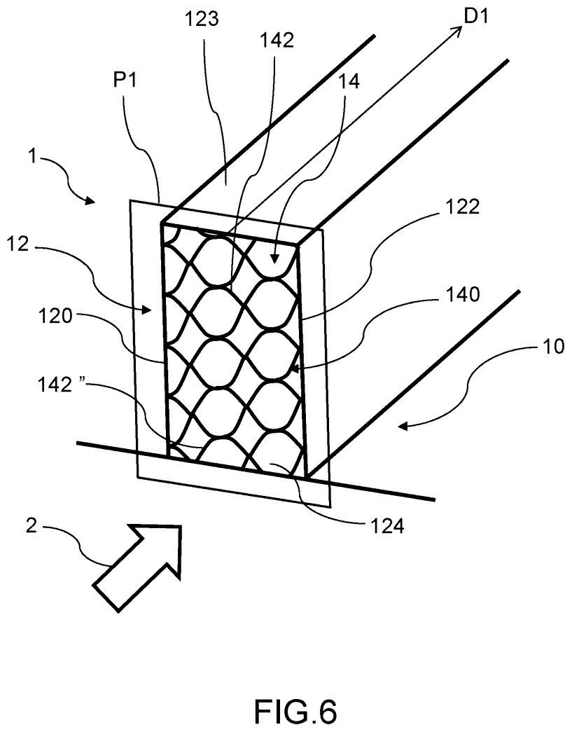

Nevertheless, it can also be envisaged, as shown in FIG. 6, that the elementary pattern 140 comprises, instead of the broken vertices 142′, folded vertices 142″. A broken vertex 142′ thus has an acute angle or an obtuse angle in the elementary pattern 140. Conversely, a folded vertex 142″ highlights a folding angle or a fold angle.

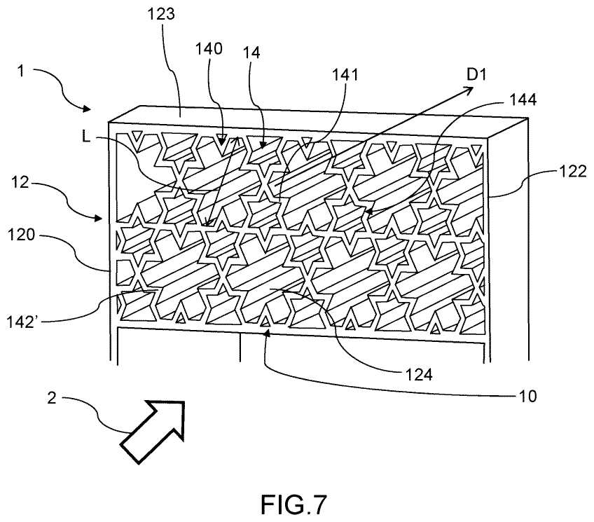

FIG. 7 shows a preferential configuration of the cooling fin 12 comprising the heat exchanger 14 of which the fractal structure has an elementary pattern of polygonal shape comprising a plurality of sides 141 and broken vertices 142′. Furthermore, the elementary pattern 140 can be likened to a fractal pattern of the snowflake type. More precisely, the elementary pattern 140 of the heat exchanger 14 in FIG. 7 is based on a fractal geometry of Koch type.

In other words, the elementary pattern 140 is obtained from a segment, for example a side 141, to which an elementary modification is applied recursively. Moreover, each time the elementary modification is applied to each straight line segment, namely a side 141, the total perimeter of the elementary pattern 140 is multiplied by a predefined value. By way of indicative example, this value is four thirds.

The fact that the heat exchanger 14 comprises a fractal structure of Koch snowflake type thus has the advantage of making it possible to increase the perimeter of the elementary pattern at each elementary modification step so as to increase the additional exchange surface 142 of the heat exchanger 14 and thus to improve the heat exchange capacity between the heat exchanger 14 and the heat-transfer fluid 2.

As a variant, any other shape of elementary pattern of fractal type complying with a deterministic rule can be envisaged in the heat exchanger 14. A deterministic rule is understood to mean a repeated modification on the structure of the heat exchanger leading to the generation of an elementary pattern 140 that is identical throughout the heat exchanger 14.

Moreover, in order to fill the space available in the cavity 124, i.e. the surface between the first wall 120 and the second wall 122 in the plane P1, as well as possible, the heat exchanger 14 can comprise a second elementary pattern 144. The second elementary pattern 144 is then of complementary shape and dimensions to the elementary pattern 140 contained in the heat exchanger 14. Thus, by way of indicative example, in the configuration shown in FIG. 7, the second elementary pattern 144 is a star pattern of which the shape is complementary to the Koch snowflake elementary pattern 140, and this advantageously makes it possible to position the second elementary pattern 144 in the shape of a star between three elementary patterns 140 that are adjacent to one another.

Furthermore, the second elementary pattern 144 may have dimensions smaller than the dimensions of the elementary pattern 140, as shown in FIG. 7. Specifically, the perimeter of the elementary pattern 140 in the shape of a Koch snowflake is of higher value than the perimeter of the second elementary pattern 144 of star shape.

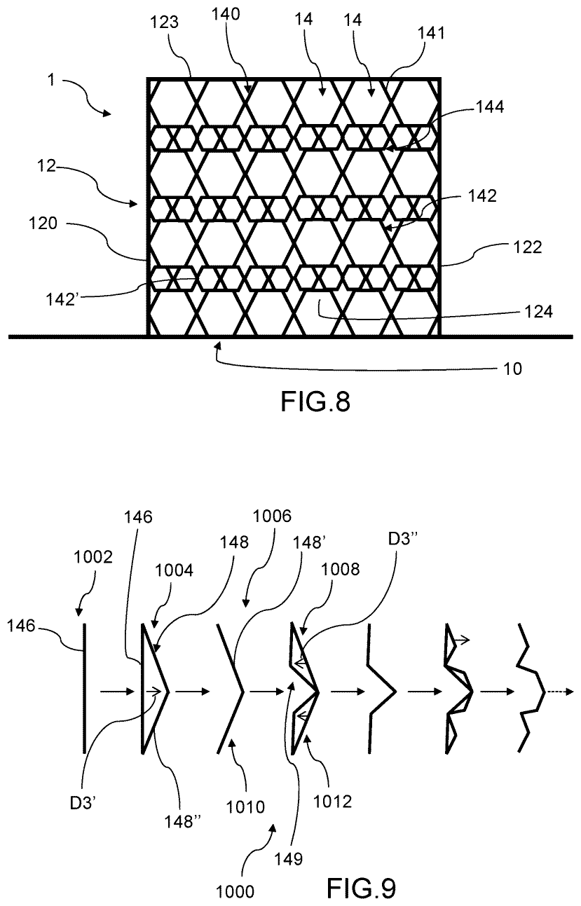

In addition, it can be envisaged, as shown in FIG. 8, that the second elementary pattern 144 is a pattern identical to the elementary pattern 140. The heat exchanger 14 then comprises an elementary pattern 140 and 144 but reproduced in two different dimensions. Consequently, it can also be envisaged that the dimensions of the second elementary pattern 144 are smaller by half than the dimensions of the elementary pattern 140. Thus, the perimeter of the second elementary pattern 144 represents half the perimeter of the elementary pattern 140. This configuration has the advantage of allowing an excellent distribution of the fractal structure in the heat exchanger 14 while at the same time making the machining of the heat exchanger 14 easier.

Other proportions between the elementary pattern 140 and the second elementary pattern 144 can also be envisaged.

Furthermore, FIG. 9 shows a method 1000 for manufacturing the cooling fin 12 in FIG. 7. More precisely, the manufacturing method 1000 focuses on the repetitive modification of a segment or a side 141 by self-similarity of shape.

The method 1000 of manufacturing by self-similarity is a repetition of geometric modification according to a predefined logic on the various scales of the model, the latter being repeated on each sub-model that appears by the putting in place of the geometric modification logic, being repeated on the subdivisions created by the previous step, and so on.

The general shape of the additional heat exchange surface 142 of the heat exchanger 14 is defined by a succession of mathematical and/or geometric operations applied to an original outline of said heat exchanger 14.

The method 1000 comprises the following steps:

A selection 1002 of an individual section 146 of the additional exchange surface 142 of the heat exchanger 14. This individual section 146 is a length representing, in the plane P1, the projected additional heat exchange surface 142. It may be envisaged that this individual section 146 is a side 141 of an elementary pattern 140 serving as a basis for the manufacture of a more complex fractal structure.

An angular modification 1004 of the individual section 146 of the additional exchange surface 142 in a first modification direction D3′. The angular modification consists in creating an isosceles triangle 148 of which the large base is the selected individual section 146 of the additional exchange surface 142, in the first modification direction D3′. The isosceles triangle 148 then comprises two subdivided sides 148′ and 148″ and a height equal to the length of the selected individual section 146 of the additional exchange surface 142 multiplied by a predefined factor k. Consequently, the isosceles triangle 148 is open on the large base.

The factor k is a value defined as a function of the desired angle between the two subdivided sides 148′ and 148″. Furthermore, the value of the factor k may be defined in a fixed manner or may be variable.

This is then followed by a step 1006 of selecting one subdivided side 148′from among the two subdivided sides 148′, 148″, then an angular modification 1008 of the selected subdivided side 148′in a second modification direction D3″. According to one aspect of the invention, the second modification direction D3″ may intersect or be parallel to the first modification direction D3′. The large base of this new isosceles triangle 149, namely the subdivided side 148′, is then open.

In addition, similarly to steps 1006 and 1008, a step 1010 of selecting the other subdivided side 148″ from among the two subdivided sides 148′ and 148″, and a step 1012 of angularly modifying the selected other subdivided side 148″ in the second modification direction D3″.

In addition, the method 1000 may also comprise a step of repeating the preceding steps following the angular modification step 1012.

In order to generate a fractal structure of Koch snowflake type, the first modification direction D3′ and the second modification direction D3″ intersect one another. Nevertheless, the geometric repetition of the elementary pattern and of the associated geometric modification can also be envisaged in order to obtain a Mandelbrot set, a Serpiński carpet structure or a Serpiński cube structure in three dimensions or else a Julia set.

As a variant, it can also be envisaged that the first modification direction D3′ and the second modification direction D3″ are parallel to each other and that the second modification direction D3″ is substantially opposite to the first modification direction D3′.

In other words, generation can be envisaged, by way of the manufacturing method 1000, from a straight line segment, namely the individual section 146, by recursively modifying each straight line segment in the following way:

By first dividing the straight line segment, i.e. the individual section 146, into two segments of equal length, namely the two subdivided sides 148′ and 148″, then by constructing any triangle having as base the selected initial segment, then by removing the straight line segment that was the base of the triangle during the construction of the triangle.

It is thus possible to repeat these steps in the second modification direction D3″.

Furthermore, the number of geometric modifications of fractal type, i.e. the number of repeats of the steps 1002, 1004, 1006, 1008, 1010 and 1012, can be defined in advance, and for example between one and six. The limit on the number of the repeats or the number of applications of geometric modifications is linked to the fineness of resolution of the machine used. Since this resolution increases as the machines evolve, a greater number of repeats will be possible in the future. The example presented is linked to the current capabilities of the machines.

In addition, the angular modification consisting in the creation of the triangle can be replaced by an angular modification consisting in the creation of a square for example, or else of a rectangle or else of a right-angled triangle, or else a triangular folding generating a fold angle as mentioned above.

By way of indicative example, it may be envisaged that the heat exchange surface 10, the first wall 120, the second wall 122, the upper connection 123 or the heat exchanger 14 are obtained from a metallic material. As a variant, any material having good thermal conductivity can be envisaged. As a variant, any material having good stiffness can be envisaged.

By way of indicative example, it may be envisaged that the heat-transfer fluid 2 is air. As a variant, any fluid, liquid or gaseous, having a good heat extraction capacity can be envisaged. As a variant, any fluid can be envisaged.

The invention therefore relates to a cooling device 1 comprising a plurality of cooling fins 12 exchanging by convection with a heat-transfer fluid 2 so as to allow heat to be extracted from the cooling device in the direction of the heat-transfer fluid 2 and to a shape of cooling fin comprising a heat exchanger 14 deduced from a geometric change of fractal type by self-similarity of shape. This fractal architecture has the advantage of making it possible to increase the heat exchange surface of the cooling fin and to improve the heat exchange without impacting the pressure of the heat-transfer fluid 2 that passes through the cooling fin 12. In other words, the invention solves the problem of increasing the heat exchange surface in order to optimize the heat exchange without significantly increasing the pressure drops associated with an increase in the frontal surface.

The applications are linked to the fields of heat exchange, typically between hot air coming from electronic equipment and a network of water at lower temperature.

Furthermore, operation using two fluids exchanging heat can also be envisaged.

The invention makes it possible to increase the efficiency of exchanges between these two fluids without constraining one or the other in terms of pressure drops.

It can also be used to allow the cooling of an electronic component, by the shape of the fins used for the thermal dissipation to a fluid such as water or air.

By way of indicative example, the means for producing such a cooling fin 12 and such a heat exchanger 14 comprising the fractal structure may be 3D printing, preferably metallic.

Extraction of these profiles by metal extrusion dies is also conceivable.

1. A cooling device comprising at least one cooling fin, the device being configured to allow a heat-transfer fluid to circulate along the at least one cooling fin in a first direction (D1), a heat exchange being able to be carried out by convection between the at least one cooling fin and the heat-transfer stream, the cooling fin comprising:
a heat exchange surface configured to allow the heat exchange with the heat-transfer fluid,
a first wall and a second wall, the first wall and the second wall extending in a plane substantially parallel to the first direction (D1) and substantially perpendicular to the heat exchange surface,
a cavity contained between the first wall and the second wall, the heat-transfer fluid circulating in the cavity, and
a heat exchanger contained in the cavity and connected to the heat exchange surface, the heat exchanger having a fractal structure in a plane (P1) perpendicular to the first direction (D1) of the heat-transfer fluid, the heat exchanger comprising repeats of an elementary pattern.

2. The cooling device as claimed in claim 1, wherein the heat exchanger is connected to the first wall and to the second wall.

3. The cooling device as claimed in claim 1, wherein the heat exchanger is configured to maximize the heat exchange surface.

4. The cooling device as claimed in claim 1, wherein the elementary pattern comprises a broken vertex.

5. The cooling device as claimed in claim 1, wherein the elementary pattern comprises a largest dimension less than 12 millimeters.

6. The cooling device as claimed in claim 1, wherein the heat exchanger comprises a second elementary pattern, the second elementary pattern being of dimensions smaller than the dimensions of the elementary pattern.

7. The cooling device as claimed in claim 1, wherein the heat exchanger comprises an additional exchange surface, the additional exchange surface representing at least a quarter of the surface contained in the cavity of the cooling fin in the plane (P1) perpendicular to the direction (D1) of the heat-transfer fluid.

8. The cooling device as claimed in claim 1, wherein the elementary pattern is a polygonal pattern.

9. The cooling device as claimed in claim 8, wherein the polygonal pattern is open on at least one side of the polygonal pattern.

10. The cooling device as claimed in claim 1, wherein the second elementary pattern is a pattern identical to the elementary pattern.

11. The cooling device as claimed in claim 10, wherein the dimensions of the second elementary pattern are smaller by half than the dimensions of the elementary pattern.

12. The cooling device as claimed in claim 1, wherein the heat exchanger comprises a self-similar fractal structure.

13. A method for manufacturing a cooling fin of a cooling device as claimed in claim 1, the heat exchanger comprising an additional heat exchange surface, the method comprising the following steps:
selecting an individual section of the additional exchange surface of the heat exchanger,
angularly modifying the individual section of the additional exchange surface in a first modification direction (D3′), the angular modification consisting in creating an isosceles triangle of which the large base is the selected individual section of the additional exchange surface, in the first modification direction (D3′), the isosceles triangle comprising two subdivided sides, and of which the height is equal to the length of the selected individual section of the additional exchange surface multiplied by a predefined factor k, the isosceles triangle being open on the large base,
selecting a subdivided side from among the two subdivided sides,
angularly modifying the selected subdivided side in a second modification direction (D3″) that intersects the first modification direction (D3′),
selecting the other subdivided side from among the two subdivided sides,
angularly modifying the selected other subdivided side in the second modification direction (D3″), and
repeating the previous steps.

14. The method for manufacturing a cooling fin as claimed in claim 14, wherein the second modification direction (D3″) is substantially opposite to the first modification direction (D3′).

15. The cooling device as claimed in claim 1, wherein the elementary pattern comprises a folded vertex.
